(19) United States
(12) Patent Application Publication
(10) Pub. No.: US 2010/0149473 A1
(43) Pub. Date: Jun. 17, 2010

(54) PIXEL ARRAY AND MANUFACTURING METHOD THEREOF

(75) Inventors: Tsai-Hua Guo, Taipei County (TW); Maw-Song Chen, Taipei City (TW); Kuo-Yu Huang, Hsinchu County (TW); Te-Chun Huang, Taipei County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: AU OPTRONICS CORPORATION, Hsinchu (TW)

(21) Appl. No.: 12/371,927

(22) Filed: Feb. 17, 2009

(30) Foreign Application Priority Data
Dec. 12, 2008 (TW) 97148645

(51) Int. Cl. G02F 1/1333; H01L 21/768

(52) U.S. Cl. 349/122; 438/29; 257/E21.532

(57) ABSTRACT

A pixel array includes a substrate, scan lines, data lines, active devices, first pads, second pads, first wires, second wires, an insulating layer, an organic planarization layer, first pad electrodes, second pad electrodes and pixel electrodes. The substrate has a display area and a non-display area. The scan lines and the data lines are disposed in the display area. The active devices are disposed in the display area and electrically connected to the scan lines and the data lines. The first and second pads are disposed in the non-display area. The first and second wires are disposed in the non-display area and respectively connected to the first and second pads. The organic planarization layer covers the insulating layer. The first and second pad electrodes are disposed on the organic planarization layer in the non-display area. The pixel electrodes are disposed on the organic planarization layer in the display area.

### CROSS-REFERENCE TO RELATED APPLICATION

This application claims the priority benefit of Taiwan application serial no. 97148645, filed Dec. 12, 2008. The entirety of the above-mentioned patent application is hereby incorporated by reference herein and made a part of specification.

### BACKGROUND OF THE INVENTION

1. Field of the Invention

The present invention generally relates to a semiconductor device array structure. More particularly, the present invention relates to a pixel array and a manufacturing method thereof for improving productive yields of liquid crystal display panels.

2. Description of Related Art

In general, a liquid crystal display panel is mainly formed from a thin film transistor array substrate, a liquid crystal layer, and a color filter substrate. During the fabrication of a thin film transistor array substrate, a plurality of pixel arrays are usually simultaneously formed on a substrate, and pads and testing circuits are timely and appropriately formed on the substrate. The pads are then connected to chips, and the main function of the testing circuits is to apply a testing voltage to each pixel array, so as to detect whether the pixels in the pixel arrays function well. Usually, a testing process is performed after the chips are bonded to the substrate. If the result of test indicates abnormal, the chip bonding process is reworked and the testing process is repeated. However, in the present structure of pixel array, the reworking of the chip bonding may lead to malfunctions of the pads.

FIG. 1A is a cross-sectional view showing a pad of a conventional pixel array. FIG. 1B is a schematic view showing the reworking of the pixel array being bonded with a chip. Referring to FIG. 1A, the pad 10 of the conventional pixel array includes a first metal layer 30 and a second metal layer 40 both on a substrate 20, a gate insulating layer 50, an insulating layer 60, an organic planarization layer 70 and a pad electrode 80. The gate insulating layer 50 is disposed between the first metal layer 30 and the second metal layer 40. The insulating layer 60 and the organic planarization layer 70 covers the first metal layer 30 and the second metal layer 40, and the insulating layer 60 and the organic planarization layer 70 have a first contact via 72 and the second contact via 74. The pad electrode 80 is electrically connected to the first metal layer 30 and the second metal layer 40 through the first contact via 72 and the second contact via 74, respectively. Then, a chip (not shown) is bonded to the substrate 20 by electrically contacting the chip to the pad electrode 80. Through the pad electrode 80, the chip can be electrically connected to the first metal layer 30 and the second metal layer 40 of the pad 10.

The pad electrode 80 is formed on a surface of the organic planarization layer 70, and the adhesion force between the organic planarization layer 70 and the inorganic insulating layer 60 is insufficient. Due to that, after the chip is bonded on the pad electrode 80, the organic planarization layer 70 may be peeled from the inorganic insulating layer 60 and the pad electrode 80 may be broken when performing a reworking process to remove the chip from the pad electrode 80. Finally, the electrical connection between the first metal layer 30 and the second metal layer 40 is broken and the pad 10 goes defect.

Although some technique has been proposed by removing the organic planarization layer 70 on the pad 10 to prevent the broken of the pad electrode 80 in the reworking of chip bonding, an additional removing process is required to remove the organic planarization layer 70, which raises high manufacturing cost and time.

### SUMMARY OF THE INVENTION

Accordingly, the present invention is directed to a pixel array, which prevents the broken of the pad electrode and the defect of the pad caused by the reworking process of chip bonding.

The present invention is directed to a manufacturing method of a pixel array, which prevents the broken of the pad electrode and the defect of the pad caused by the reworking process of chip bonding without addition of manufacturing process.

As embodied and broadly described herein, the present invention provides A pixel array, comprising: a substrate having a display area and a non-display area; a plurality of scan lines and a plurality of data lines, both disposed in the display area; a plurality of active devices disposed in the display area and electrically connected to the scan lines and the data lines; a plurality of first pads and a plurality of second pads, both disposed in the non-display area, wherein the first pads and the second pads are arranged alternately and disposed in different layers; a plurality of first wires and a plurality of second wires, both disposed in the non-display area and connected to the first pads and the seconds respectively, wherein a material of the first wires is substantially the same as a material of the first pads, and a material of the second wires is substantially the same as a material of the second pads; an insulating layer covering the data lines, the scan lines, the active devices, the first pads, the second pads, the first wires and the second wires; an organic planarization layer covering the insulating layer, wherein the organic planarization layer and the insulating layer have a plurality of first contact vias, a plurality of second contact vias and a plurality of third contact vias, each of the first contact vias expose the first corresponding pad, each of the second contact vias expose the second corresponding pad, and each of the third contact vias expose a portion of the corresponding active device; a plurality of first pad electrodes disposed on the organic planarization layer in the non-display area, wherein the first pad electrodes electrically connected to the first pads through the first contact vias; a plurality of second pad electrodes disposed on the organic planarization layer in the non-display area, wherein the second pad electrodes electrically connected to the second pads through the second contact vias; and a plurality of pixel electrodes disposed on the organic planarization layer in the display area, wherein the pixel electrodes electrically connected to the active devices through the third contact vias.

According to an embodiment of the present invention, the material of the first pads is different from the material of the second pads.

According to an embodiment of the present invention, the first wires and the second wires are electrically connected to the data lines.

According to an embodiment of the present invention, the first wires and the second wires are electrically connected to the scan lines.

According to an embodiment of the present invention, a part of the first and second wires are electrically connected to the data lines, and another part of the first and second wires are electrically connected to the scan lines.

According to an embodiment of the present invention, a thickness of the organic planarization layer in the non-display area is smaller than that of the organic planarization layer in the display area.

According to an embodiment of the present invention, the pixel array further comprises a plurality of first connecting lines and a plurality of second connecting lines, both disposed in the non-display area, wherein the first connecting lines are electrically connected to the first pads, and the second connecting lines are electrically connected to the second pads.

According to an embodiment of the present invention, in the non-display area, the organic planarization layer and the insulating layer further have a plurality of fourth contact vias, the fourth contact vias expose the first connecting line, and the first pad electrode are electrically connected to the first connecting lines through the fourth contact vias.

According to an embodiment of the present invention, the pixel array further comprises a plurality of switching devices, wherein the substrate further has a testing area, the switching devices are disposed in the testing area, and the switching devices are electrically connected to the first connecting lines and the second connecting lines.

According to an embodiment of the present invention, the pixel array further comprises a plurality of testing devices disposed in the testing area, wherein the testing devices are electrically connected to the switching devices.

According to an embodiment of the present invention, the pixel array further comprises a plurality of testing devices, wherein the substrate further has a testing area, the testing devices are disposed in the testing area, and the testing devices are electrically connected to the first connecting lines and the second connecting lines.

A manufacturing method of a pixel array is also provided. The manufacturing method comprises: providing a substrate having display area and a non-display area; forming a plurality of scan lines, a plurality of data lines and a plurality of active devices electrically connected to the scan lines and the data lines in the display area; forming a plurality of first wires and a plurality of first pads electrically connected to the first wires in the non-display area at the same time; forming a plurality of second wires and a plurality of second pads electrically connected to the second wires in the non-display area at the same time, wherein the first pads and the second pads are disposed in different layers and arranged alternately; forming an insulating layer on the substrate for covering the data lines, the scan lines, the active devices, the first pads, the second pads, the first wires and the second wires; forming an organic planarization layer on the insulating layer, wherein the organic planarization layer has a plurality of first openings, a plurality of second openings and a plurality of third openings; etching the insulating layer by using the organic planarization layer as an etching mask to form a plurality of first contact vias, a plurality of second contact vias and a plurality of third contact vias, wherein each of the first contact vias expose the corresponding first pad, each of the second contact vias expose the corresponding second pad, and each of the third contact vias rexpose a portion of the corresponding active device; and forming a plurality of first pad electrodes and a plurality of second pad electrodes on the organic planarization layer in the non-display area, and forming a plurality of pixel electrodes on the organic planarization layer in the display area, wherein the first pad electrodes are electrically connected to the first pads through the first contact vias, the second pad electrodes are electrically connected to the second pads through the second contact vias, and the pixel electrodes are electrically connected to the active devices through the third contact vias.

According to an embodiment of the present invention, a material of the first pads is different from a material of the second pads.

According to an embodiment of the present invention, the first wires and the second wires are electrically connected to the data lines.

According to an embodiment of the present invention, the first wires and the second wires are electrically connected to the scan lines.

According to an embodiment of the present invention, a part of the first and second wires are electrically connected to the data lines, and another part of the first and second wires are electrically connected to the scan lines.

According to an embodiment of the present invention, the manufacturing method further comprises reducing a thickness of the organic planarization layer in the non-display area such that the thickness of the organic planarization layer in the non-display area is smaller than that of the organic planarization layer in the display area.

According to an embodiment of the present invention, the manufacturing method further comprises forming a plurality of first connecting lines and a plurality of second connecting lines in the non-display area, wherein the first connecting lines are electrically connected to the first pads, and the second connecting lines are electrically connected to the second pads.

According to an embodiment of the present invention, the manufacturing method further comprises forming a plurality of fourth contact vias in the organic planarization layer and the insulating layer in the non-display area, wherein the first pad electrode are electrically connected to the first connecting lines through the fourth contact vias.

According to an embodiment of the present invention, the substrate further has a testing area, the manufacturing method further comprises forming a plurality of switching devices in the testing areas, and the switching devices are electrically connected to the first connecting lines and the second connecting lines.

According to an embodiment of the present invention, the manufacturing method further comprises forming a plurality of testing devices in the testing area, wherein the testing devices are electrically connected to the switching devices.

According to an embodiment of the present invention, the substrate further has a testing area, the manufacturing method further comprises forming a plurality of testing device in the testing area, and the testing devices are electrically connected to the first connecting lines and the second connecting lines.

Accordingly, the pads of the present invention are not electrically connected to the two metal layers through pad electrodes, and thus the defect of the pads due to the broken of the pad electrodes in the reworking process of chip bonding can be prevented. In addition, the manufacturing method of the pixel array according to the present invention can solve the aforementioned problem without any additional manufacturing process in the situation that the organic planarization layer is preserved.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a cross-sectional view showing a pad of a conventional pixel array.

FIG. 1B is a schematic view showing the reworking of the pixel array being bonded with a chip.

FIG. 2A is a top view of a pixel array according to an embodiment of the present invention.

FIG. 2B is an enlarged view of the pixel array in a non-display area and a testing area defined on a substrate as shown in FIG. 2A.

FIG. 2C is a cross-sectional view along line I-I of FIG. 2A and lines II-II and III-III of FIG. 2B.

FIG. 2D shows a chip disposed on the non-display area of the substrate as illustrated in FIG. 2A.

FIG. 2E is a top view of a pixel array according to another embodiment of the present invention.

FIG. 2F is an enlarged view of the pixel array in a non-display area and a testing area defined on a substrate according to another embodiment of the present invention.

FIGS. 3A to FIG. 3H are cross-sectional views illustrating a manufacturing method of a pixel array according to an embodiment of the present invention.

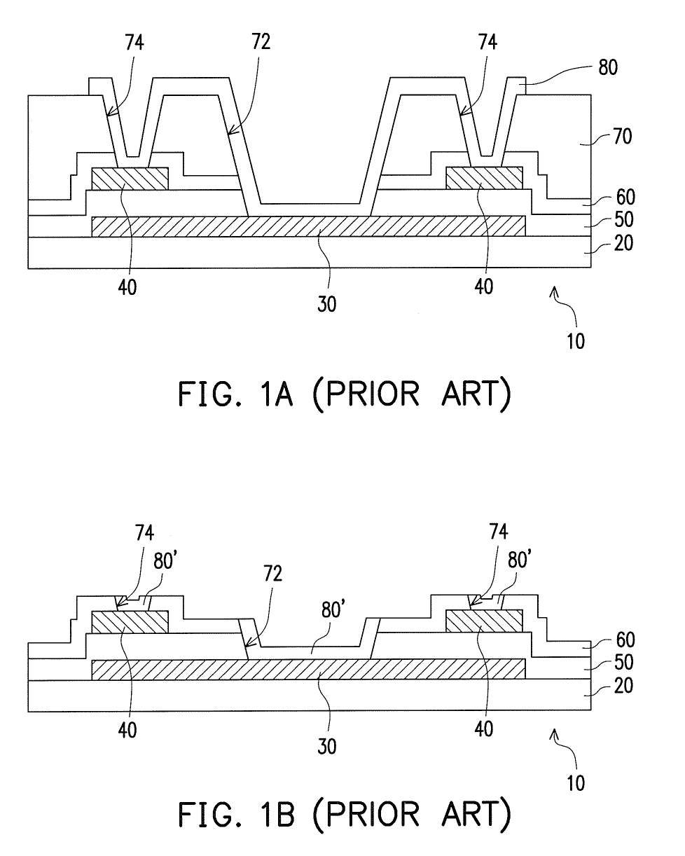

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

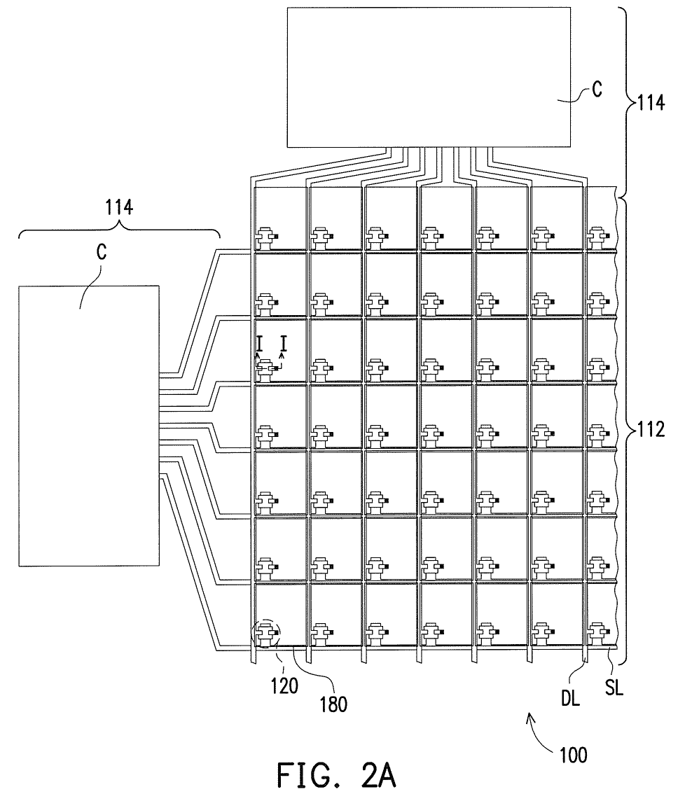

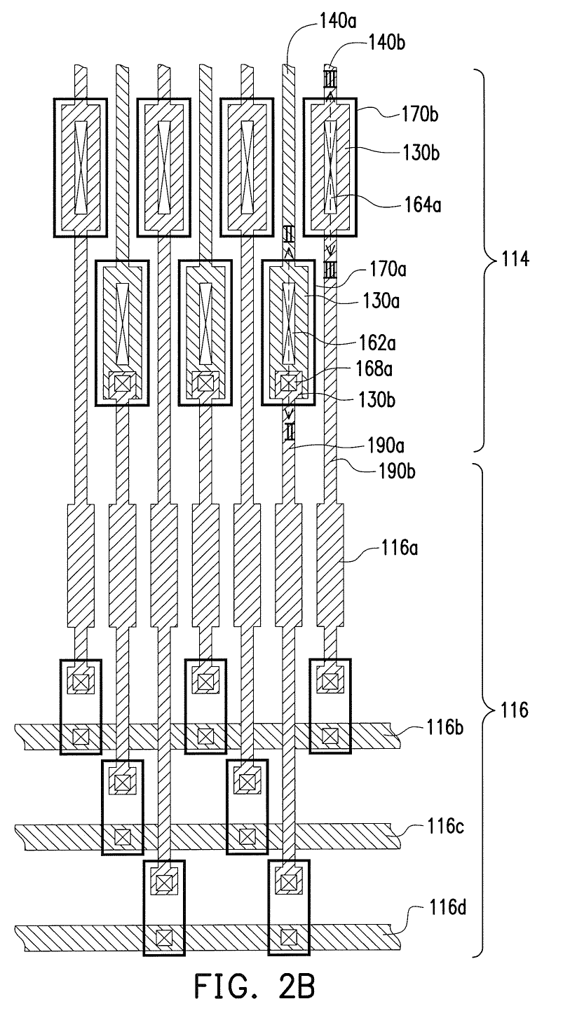

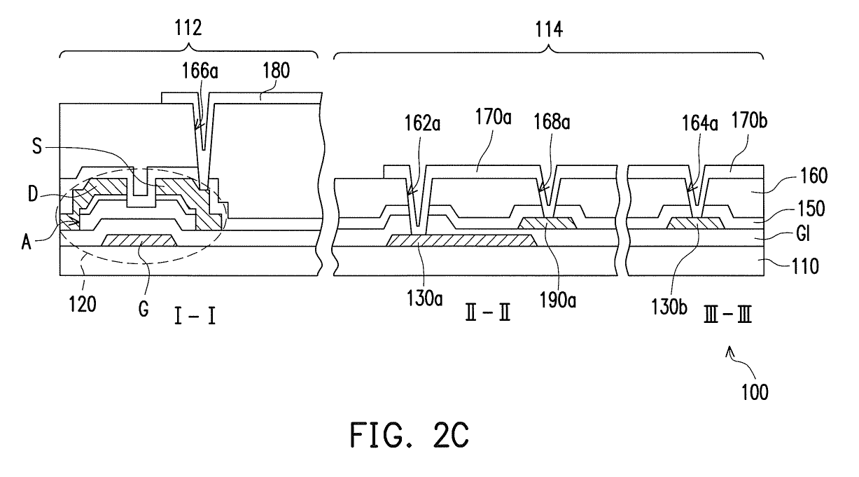

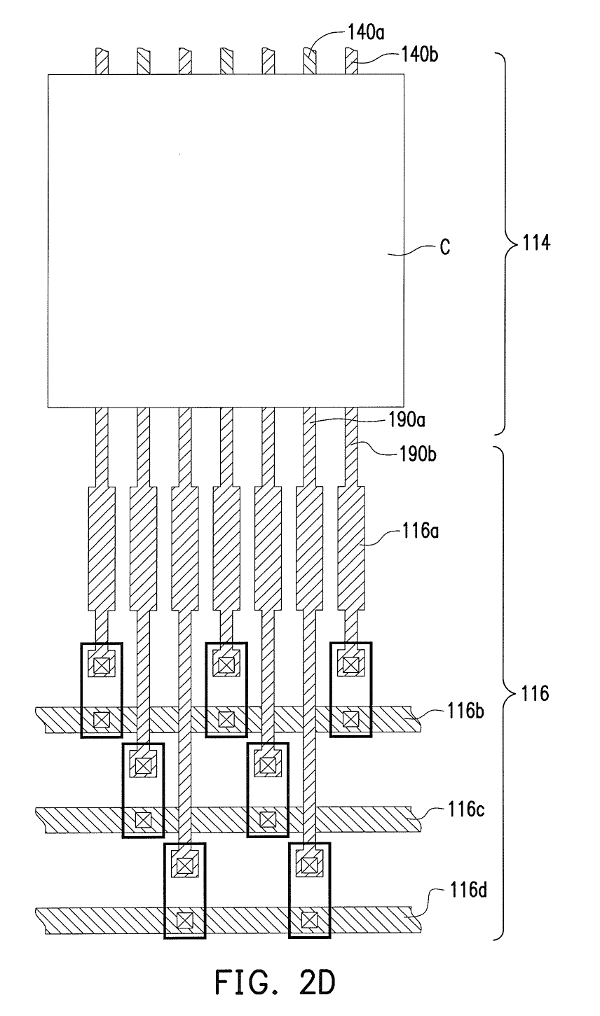

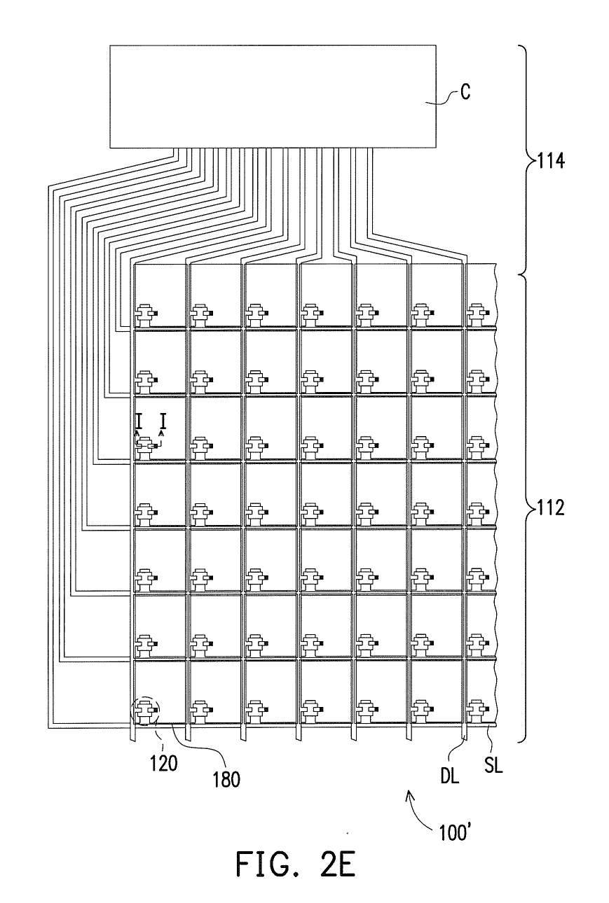

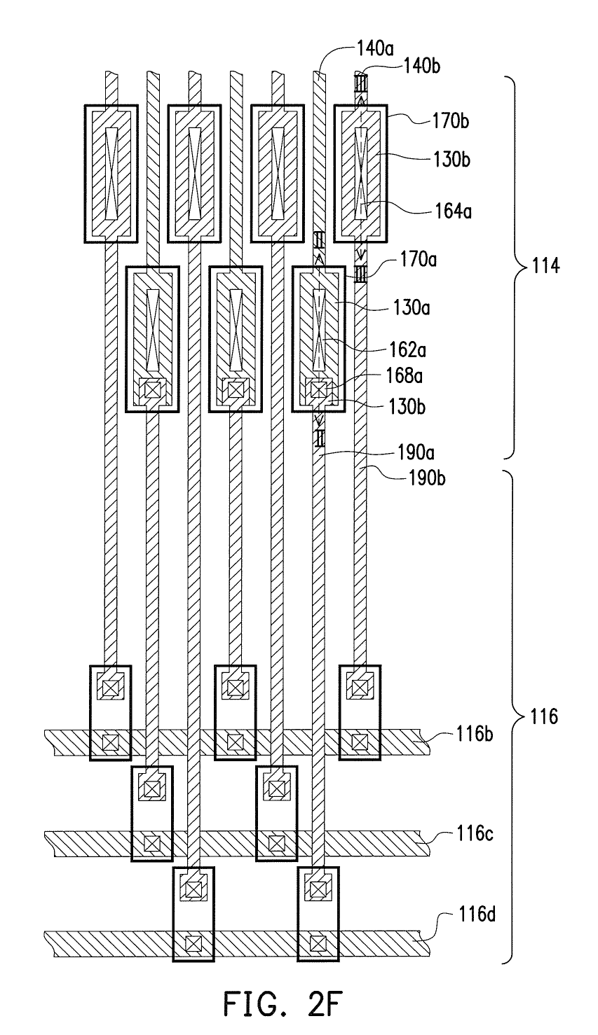

FIG. 2A is a top view of a pixel array according to an embodiment of the present invention. FIG. 2B is an enlarged view of the pixel array in a non-display area and a testing area defined on a substrate as shown in FIG. 2A. FIG. 2C is a cross-sectional view along line I-I of FIG. 2A and lines II-II and III-III of FIG. 2B. FIG. 2D shows a chip disposed on the non-display area of the substrate as illustrated in FIG. 2A. The non-display areas or the testing areas of the following pixel arrays can be identical or similar. However, the present invention is not limited thereto. In other embodiments, design of elements in the non-display area and the testing area at the side of data line can be different from that at the side of scan line.

Referring to FIGS. 2A, 2B and 2C, in this embodiment, the pixel array 100 includes a substrate 110, a plurality of scan lines SL, a plurality of data lines DL, a pluggrality of active devices 120, a plurality of first pads 130a, a plurality of second pads 130b, a plurality of first wires 140a, a plurality of second wires 140b, an insulating layer 150, an organic planarization layer 160, a plurality of first pad electrodes 170a, a plurality of second pad electrodes 170b and a plurality of pixel electrodes 180.

In detail, the substrate 110 has a display area 112 and a non-display area 114. The scan lines SL and the data lines DL are disposed in the display area 112. The active devices 120 are disposed in the display area 112 and electrically connected to the scan lines SL and the data lines DL. In this embodiment, each active device 120 comprises a gate G, a gate insulating layer GI, an active layer A, a source S and a drain D, wherein the gate G is disposed on the substrate 110, and the gate insulating layer GI covers the gate G. The active layer A is disposed on the gate insulating layer GI and is a double layered structure constituted by amorphous silicon (i.e. channel layer) and N type heavy doped amorphous silicon (i.e. ohmic contact layer). The source and the drain D are respectively disposed above a part of the active layer A.

The first pads 130a and the second pads 130b are disposed in the non-display area 114 of the substrate 110, in particular, the first pads 130a and the second pads 130b are arranged alternately. In this embodiment, the gate insulating layer GI is disposed in the display area 112 and the non-display area 114 of the substrate 110 and covers the first pads 130a on the substrate 110. The second pads 130b are disposed on the gate insulating layer GI. In other words, the first pads 130a and the second pads 130b are disposed in different layers. In this embodiment the material of the first pads 130a is different from that of the second pads 130b. However, the present invention is not limited thereto. In other embodiments, the material of the first pads 130a can be identical to that of the second pads 130b.

The first wires 140a and the second wires 140b are disposed in the non-display area 114 of the substrate 110 and respectively connected to the first pads 130a and the second pads 130b. The material of the first wires 140a is identical to that of the first pads 130a, and the material of the second wires 140b is identical to that of the second pads 130b. Specifically, the first wires 140a and the first pads 130a are disposed in the same layer, and the second wires 140b and the second pads 130b are disposed in the same layer. In this embodiment, since the first pads 130a and the second pads 130b are disposed in different layers, the first wires 140a and the second wires 140b respectively connected to the first pads 130a and the second pads 130b are also disposed in different layers.

The insulating layer 150 covers the data lines DL, the scan lines SL, the active devices 120, the first pads 130a, the second pads 130b, the first wires 140a and the second wires 140b. The organic planarization layer 160 covers the insulating layer 150, wherein the organic planarization layer 160 and the insulating layer 150 both has a plurality of first contact vias 162a (FIG. 2C schematically shows one first contact via 162a), a plurality of second contact vias 164a (FIG. 2C schematically shows one second contact via 164a) and a plurality of third contact vias 166a (FIG. 2C schematically shows one third contact via 166a). The first contact via 162a exposes the corresponding first pad 130a, the second contact via 164a exposes the corresponding second pad 130b, and the third contact via 166a exposes a part of the corresponding active device 120. More particularly, in this embodiment, the thickness of the organic planarization layer 160 in the non-display area 114 is smaller than that of the organic planarization layer 160 in the display area 112, which facilitates bonding the chip C onto the non-display area 114 as shown in FIG. 2D, and therefore improves the yields of bonding process between the chip C and the non-display area 114.

The first pad electrodes 170a are disposed on the organic planarization layer 160 in the non-display area 114, and the first pad electrodes 170a are electrically connected to the first pads 130a through the corresponding first contact vias 162a. The second pad electrodes 170b are disposed on the organic planarization layer 160 in the non-display area 114, and the second pad electrodes 170b are electrically connected to the second pads 130b through the corresponding second contact vias 164a. The pixel electrodes 180 are disposed on the organic planarization layer 160 in the display area 112, and the pixel electrodes 180 are electrically connected to the active devices 120 through the corresponding third contact vias 166a.

In addition, referring to FIG. 2B, in this embodiment, the pixel array 100 further comprises a plurality of first connecting lines 190a and a plurality of second connecting lines 190b. The first connecting lines 190a and the second connecting lines 190b are disposed in the non-display area 114, wherein the first connecting lines 190a are respectively connected to the first pads 130a, and the second connecting lines 190b are electrically connected to the second pads 130b. The organic planarization layer 160 and the insulating layer 150 in the non-display area 114 both further has a plurality of fourth contact vias 168a, wherein the fourth contact vias 168a expose the first connecting lines 190a, and the first pad electrodes 170a are electrically connected to the first connecting lines 190a through the corresponding fourth contact vias 168a. Furthermore, the first connecting lines 190a and the second connecting lines 190b are disposed in the same layer.

According to embodiments of the present invention, the substrate 110 may further comprise a testing area 116, on which a plurality of switching devices 116a, first testing devices 116b, second testing devices 116c and third testing devices 116d are disposed. Each switching device 116a is electrically connected to the corresponding first connecting line 190a and the corresponding second connecting line 190b. The first testing devices 116b, the second testing devices 116c and the third testing devices 116d are electrically connected to the switching devices 116a.

It should be noted that the testing area 116 of the present invention is not limited to the aforementioned description. Although the above-mentioned testing area 116 is provided with a plurality of switching devices 116a electrically connected to the first testing devices 116b, the second testing devices 116c and the third testing devices 116d, however, in other embodiments, as shown in FIG. 2F, the first testing devices 116b, the second testing devices 116c and the third testing devices 116d can be directly electrically connected to the first connecting lines 190a and the second connecting lines 190b respectively without the switching devices 116a, which still belongs to means of the present invention and does not depart from the scope of the present invention.

Accordingly, in this embodiment, the first pads 130a and the second pads 130b are arranged alternately in the non-display area 114 of the substrate 110 and disposed in different layers. The first pads 130a and the second pads 130b are directly connected with the chip C (as shown in FIG. 2D), which requires no pad electrode to electrically connect two metal layers (so called “turn-line”) as proposed in the conventional art. Therefore, as the chip C needs to be bonded again in reworking process, the problem that the failure of electrical connection between the two metal layers of the pads and the chip caused by the defect of the pad electrode in the conventional art can be prevented. In addition, the thickness of the organic planarization layer 160 in the non-display area 114 is smaller than that of the organic planarization layer 160 in the display area 112, which can preserve the organic planarization layer 160 while preventing the defect of the pads due to the broken of the pad electrodes in the reworking process of chip bonding and thus improve the yields of chip bonding process.

It is noted that the pixel array 100 of this embodiment is suitable for panels in a large scale, wherein the first wires 140a and the second wires 140b disposed at a side of the pixel array 100 is electrically connected to the data lines DL, and the first wires 140a and the second wires 140b disposed at another side of the pixel array 100 is electrically connected to the scan line SL, which provides no limitation to the present invention. Additionally, in another embodiment, the first pads 130a and the second pads 130b arranged alternately are disposed in only the non-display area 114 besides the data lines DL. That is, the first wires 140a and the second wires 140b are electrically connected to the data lines DL, while a pad structure without alternated arrangement is adopted in the non-display area 114 besides the scan line SL. In further another embodiment, the first pads 130a and the second pads 130b arranged alternately are disposed in only the non-display area 114 besides the scan lines SL. That is, the first wires 140a and the second wires 140b are electrically connected to the scan lines SL, while a pad structure without alternated arrangement is adopted in the non-display area 114 besides the data lines DL.

Furthermore, the present invention can be applied to a pixel array of a panel in small scale. In which, the non-display area and the testing area as mentioned above can be formed on only one side of the pixel array of the panel in small scale. Referring to FIG. 2E, the first wires 140a, the second wires 140b, the first pads 130a and the second pads 130b are disposed in only one side of the pixel array 100′. Therefore, a part of the first wires 140a and the second wires 140b are electrically connected to the data lines DL, while another part if electrically connected to the scan lines SL.

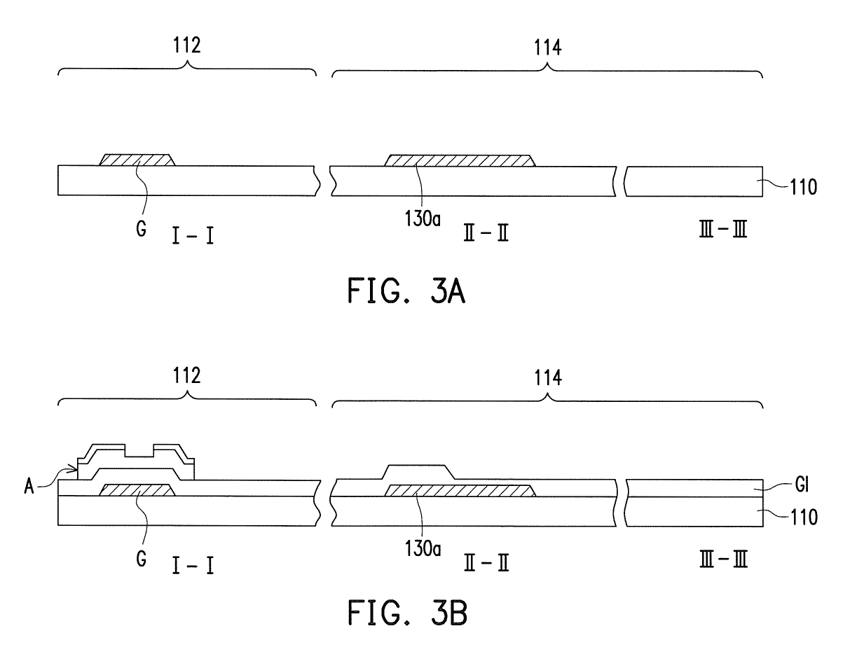

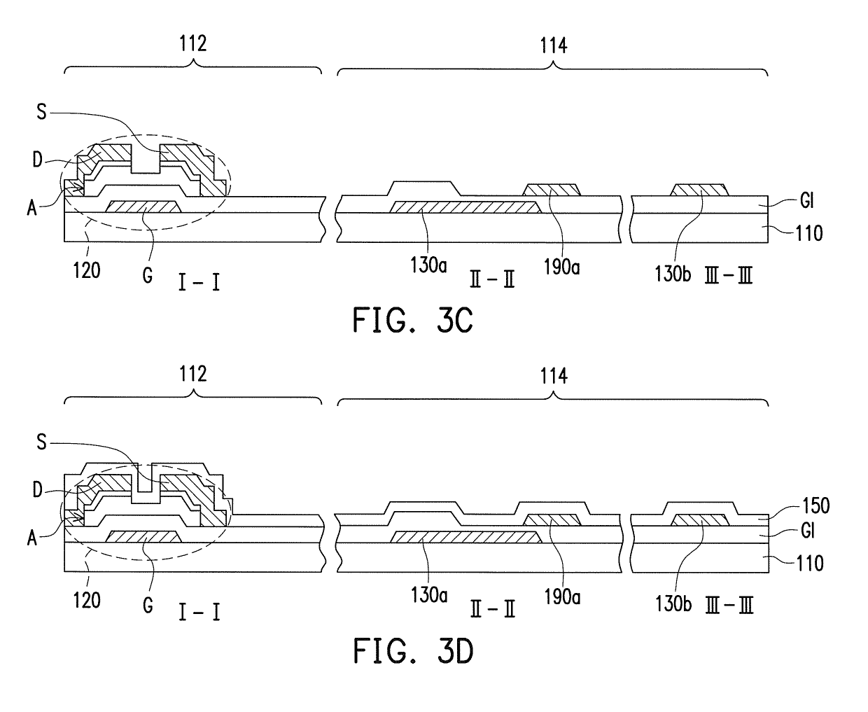

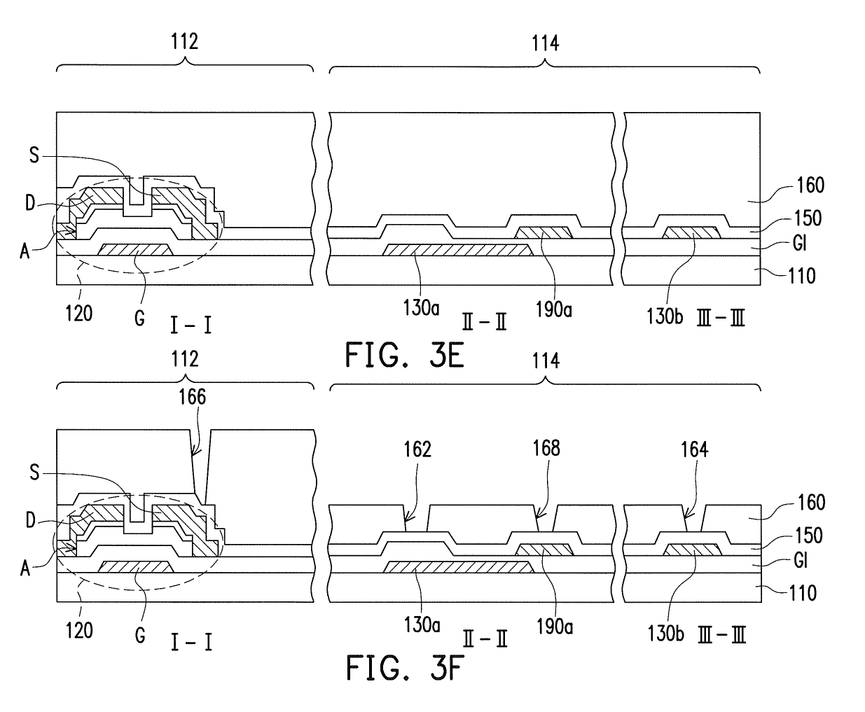

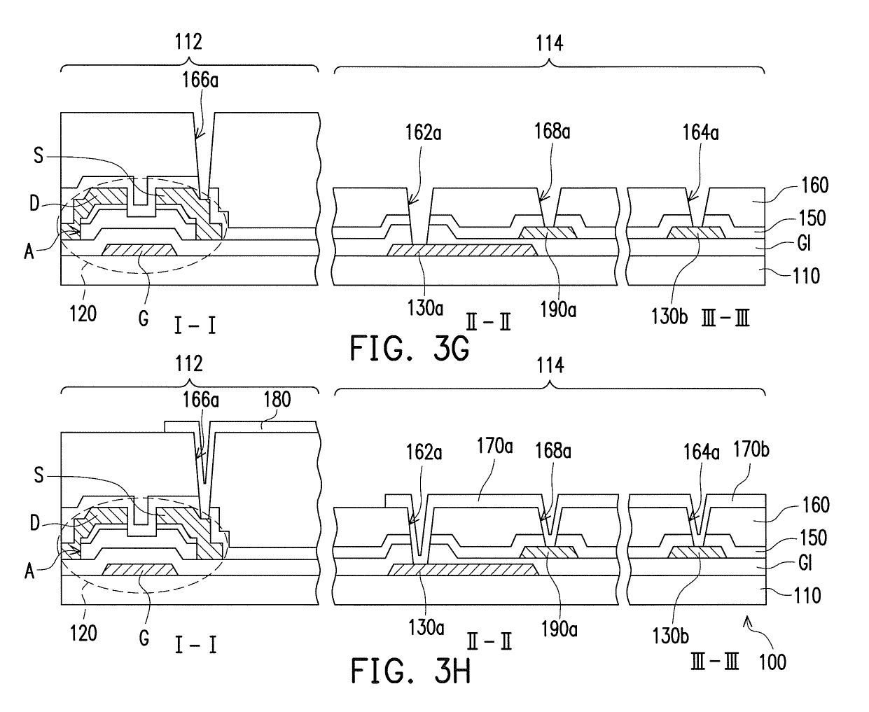

The aforementioned pixel array 100 can be formed by the following manufacturing method. The pixel array 100 as shown in FIG. 2A is taken as an example in the following illustration, and the manufacturing method of the pixel array 100 is illustrated in FIGS. 3A to 3H. It should be noted that FIGS. 3A to 3H are cross-sectional views along line I-I of FIG. 2A, line II-II and line III-III of FIG. 2B to show the manufacturing method of the pixel array 100.

FIGS. 3A to FIG. 3H are cross-sectional views illustrating a manufacturing method of a pixel array according to an embodiment of the present invention. First, referring to FIG. 3A, a substrate 110 having a display area 112 and a non-display area 114 is provided.

Then, referring to FIG. 3A, FIG. 2A and FIG. 2B, a plurality of scan lines SL and a plurality of gates G are formed in the display area 112 of the substrate 110. A plurality of first wires 140a and a plurality of first pads 130a connected to the first wires 140a are formed in the non-display area 114 of the substrate 110. The scan lines SL are electrically connected to the gates G. Practically, each gate G can be a part of the corresponding scan line SL or extended from the corresponding scan line SL, which are not limited herein. More particularly, in this embodiment, the first pads 130a and the first wires 140a are formed in the same processing step, and thus the material of the first wires 140a is identical to that of the first pads 130a.

Next, referring to FIG. 3B, a gate insulating layer GI is formed to cover the gates G in the display area 112 and the first pads 130a and the first wires 140a in the non-display area 114. Then, an active layer A is formed on the gate insulating layer GI above each gate G, wherein the active layer A is a double layered structure constituted by by amorphous silicon (i.e. channel layer) and N type heavy doped amorphous silicon (i.e. ohmic contact layer).

Next, referring to FIG. 3C, FIG. 2A and FIG. 2B, a plurality of second wires 140b and a plurality of second pads 130b connected to the second wires 140b are formed in the non-display area 114 of the substrate 110. Data lines DL are formed on the gate insulating layer GI in the display area 112 of the substrate 110. A source S and a drain D are formed above a part of each active layer A, wherein the source S is electrically connected to the corresponding data line DL. Meanwhile, a plurality of first connecting lines 190a and a plurality of second connecting lines 190b are formed in the non-display area 114 of the substrate 110. Specifically, the second connecting lines 190b are directly connected to the second pads 130b, respectively, while the first connecting lines 190a and the first pads 13 0a are isolated in different layers.

In addition, since the second pads 130b and the second wires 140b are formed in the same processing step, the material of the second wires 140b and that of the second pads 130b are identical. Furthermore, the first connecting lines 190a and the second connecting lines 190b are formed with the second pads 130b and the second wires 140b in the same processing step, and therefore the material of the first connecting lines 190a and the second connecting lines 190b are identical to that of the second wires 140b and the second pads 130b.

Particularly, in this embodiment, the first pads 130a and the second pads 130b are respectively disposed in different layers, and the first pads 130a and the second pads 130b are arranged alternately. The material of the first pads 130a and that of the second pads 130b are different, but are not limited herein. In other embodiments not shown, the material of the first pads 130a may be identical to that of the second pad 130b. Accordingly, the scan lines SL, the data lines DL and the active devices 120 electrically connected thereto are formed in the display area 112 of the substrate 110 by the aforementioned process. It is noted that the active devices 120 are in a bottom gate structure, which provides no limitation to the present invention. In other embodiments, the sequence of forming the first pads 130a and the active layers A on the substrate 110 can be altered to form active devices in a top gate structure.

It is noted that the pixel array 100 of this embodiment is suitable for panels in a large scale, wherein the first wires 140a and the second wires 140b disposed at a side of the pixel array 100 is electrically connected to the data lines DL, and the first wires 140a and the second wires 140b disposed at another side of the pixel array 100 is electrically connected to the scan line SL, which provides no limitation to the present invention. In another embodiment, the first wires 140a and the second wires 140b are disposed in only one side of the pixel array 100 and are electrically connected to the data lines DL or the scan lines SL. In further another embodiment, referring to FIG. 2E, the pixel array 100′ is suitable for display panels in a small scale, wherein a part of the first wires 140a and the second wires 140b are electrically connected to the data lines DL, while another part of the first wires 140a and the second wires 140b are electrically connected to the scan lines SL.

Then, referring to FIG. 3D, FIG. 2A and FIG. 2B, an insulating layer 150 is formed on the substrate 110, wherein the insulating layer 150 covers the data lines DL, the scan lines SL and the active devices 120 in the display area 112 and the first pads 130a, the second pads 130b, the first wires 140a and the second wires 140b in the non-display area 114.

Next, referring to FIG. 3E, an organic planarization layer 160 is formed on the insulating layer 150. Then, referring to FIG. 3F, the organic planarization layer 160 is patterned to form a plurality of first openings 162, a plurality of second openings 164, a plurality of third openings 166 and a plurality of fourth openings 168 in the organic planarization layer 160, and the thickness of the organic planarization layer 160 in the non-display area 114 is reduced by removing a part of the organic planarization layer 160, so that the thickness of the organic planarization layer 160 in the non-display area 114 is smaller than that of the organic planarization layer 160 in the display area 112. In this embodiment, the organic planarization layer 114 is patterned by using a half-tone mask. More specifically, in this embodiment, the thickness of the organic planarization layer 160 in the non-display area 114 is smaller that that in the display area 112, which facilitates bonding the chip C onto the non-display area 114 as shown in FIG. 2D, and therefore improves the yields of bonding process between the chip C and the non-display area 114.

Next, referring to FIG. 3G, the organic planarization layer 160 is adopted as an etching mask to perform an etching process to the insulating layer 150, so as to form a plurality of first contact vias 162a, a plurality of second contact vias 164a, a plurality of third contact vias 166a and a plurality of fourth contact vias 168a. In this embodiment, each first contact vias 162a exposes the corresponding first pad 130a, each second contact via 164a exposes the corresponding second pad 130b, each third contact via 166a exposes a part of the corresponding active device 120, and each fourth contact via 168a exposes the corresponding first connecting line 190a.

Next, referring to FIG. 3H, a plurality of first pad electrodes 170a and a plurality of second pad electrodes 170b are formed on the organic planarization layer 160 in the non-display area 114, and a plurality of pixel electrodes 180 are formed on the organic planarization layer 160 in the display area 112. In detail, the first pad electrodes 170a are electrically connected to the first pads 130a through the corresponding first contact vias 162a, the second pad electrodes 170b are electrically connected to the second pads 130b through the corresponding second contact vias 164a, and the pixel electrodes 180 are electrically connected to the active devices 120 through the corresponding third contact vias 166a. Furthermore, the first pad electrodes 170a are electrically connected to the first connecting lines 190a through the corresponding fourth contact vias 168a. In this embodiment, the first connecting lines 190a and the second connecting lines 190b are disposed in the same layer, and thus the first pads 130a can be electrically connected to first connecting lines 190a disposed in another layer through the transfer of the fourth contact vias 168a.

Referring to FIG. 2B, the above-mentioned manufacturing process forms a plurality of switching devices 116a, first testing devices 116b, second testing devices 116c and third testing devices 116d together in the testing area 116 of the substrate 110. The switching devices 116a are electrically connected to the first connecting lines 190a and the second connecting lines 190b, and the first testing device 116b, the second testing devices 116c and the third testing devices 116d are electrically connected to the switching devices 116a.

It should be noted that the testing area 116 of the present invention is not limited to the aforementioned description. Although the above-mentioned testing area 116 is provided with a plurality of switching devices 116a electrically connected to the first testing devices 116b, the second testing devices 116c and the third testing devices 116d, however, in other embodiments, as shown in FIG. 2F, the first testing devices 116b, the second testing devices 116c and the third testing devices 116d can be directly electrically connected to the first connecting lines 190a and the second connecting lines 190b respectively without the switching devices 116a, which still belongs to means of the present invention and does not depart from the scope of the present invention.

Accordingly, in this embodiment, the first pads 130a and the second pads 130b are arranged alternately in the non-display area 114 of the substrate 110 and disposed in different layers. The first pads 130a and the second pads 130b are directly connected with the chip C. Therefore, as the chip C needs to be bonded again in reworking process, the problem that the failure of electrical connection between the two metal layers of the pad and the chip caused by the defect of the pad electrode in the conventional art can be prevented. In addition, the organic planarization layer 160 is preserved while preventing the defect of the pads due to the broken of the pad electrodes in the reworking process of chip bonding and thus the yields of chip bonding process is improved.

In summary, the first pads and the second pads of the pixel array of the present invention are arranged alternately and disposed in different layers. The first pads and the second pads are directly connected with the pad electrodes without the “turn-line” structure. Therefore, as the chip needs to be bonded again in reworking process, the defect of the pad electrodes does not affect the electrical connection between the pads and the chip. In addition, the pixel array of the present invention can preserve the organic planarization layer while preventing the defect of the pads due to the broken of the pad electrodes in the reworking process of chip bonding and thus improve the yields of chip bonding process.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A pixel array, comprising:
a substrate having a display area and a non-display area;
a plurality of scan lines and a plurality of data lines, both disposed in the display area;
a plurality of active devices disposed in the display area, and electrically connected to the scan lines and the data lines;
a plurality of first pads and a plurality of second pads, both disposed in the non-display area, wherein the first pads and the second pads are arranged alternately and disposed in different layers;
a plurality of first wires and a plurality of second wires, both disposed in the non-display area and connected to the first pads and the seconds respectively, wherein a material of the first wires is substantially the same as a material of the first pads, and a material of the second wires is substantially the same as a material of the second pads;
an insulating layer covering the data lines, the scan lines, the active devices, the first pads, the second pads, the first wires and the second wires;
an organic planarization layer covering the insulating layer, wherein the organic planarization layer and the insulating layer have a plurality of first contact vias, a plurality of second contact vias and a plurality of third contact vias, each of the first contact vias expose the corresponding first pad, each of the second contact vias expose the corresponding second pad, and each of the third contact vias expose a portion of the corresponding active device;
a plurality of first pad electrodes disposed on the organic planarization layer in the non-display area, wherein the first pad electrodes electrically connected to the first pads through the first contact vias;
a plurality of second pad electrodes disposed on the organic planarization layer in the non-display area, wherein the second pad electrodes electrically connected to the second pads through the second contact vias; and
a plurality of pixel electrodes disposed on the organic planarization layer in the display area, wherein the pixel electrodes electrically connected to the active devices through the third contact vias.

2. The pixel array according to claim 1, wherein the material of the first pads is different from the material of the second pads.

3. The pixel array according to claim 1, wherein the first wires and the second wires are electrically connected to the data lines.

4. The pixel array according to claim 1, wherein the first wires and the second wires are electrically connected to the scan lines.

5. The pixel array according to claim 1, wherein a part of the first and second wires are electrically connected to the data lines, and another part of the first and second wires are electrically connected to the scan lines.

6. The pixel array according to claim 1, wherein a thickness of the organic planarization layer in the non-display area is smaller than that of the organic planarization layer in the display area.

7. The pixel array according to claim 1, further comprising a plurality of first connecting lines and a plurality of second connecting lines, both disposed in the non-display area, wherein the first connecting lines are electrically connected to the first pads, and the second connecting lines are electrically connected to the second pads.

8. The pixel array according to claim 7, further comprising a plurality of fourth contact vias in the organic planarization layer and the insulating layer in the non-display area, wherein the fourth contact vias expose the first connecting line, and the first pad electrode are electrically connected to the first connecting lines through the fourth contact vias.

9. The pixel array according to claim 7, further comprising a plurality of switching devices, wherein the substrate further has a testing area, the switching devices are disposed in the testing area, and the switching devices are electrically connected to the first connecting lines and the second connecting lines.

10. The pixel array according to claim 9, further comprising a plurality of testing devices disposed in the testing area, wherein the testing devices are electrically connected to the switching devices.

11. The pixel array according to claim 7, further comprising a plurality of testing devices, wherein the substrate further has a testing area, the testing devices are disposed in the testing area, and the testing devices are electrically connected to the first connecting lines and the second connecting lines.

12. A manufacturing method of a pixel array, the manufacturing method comprising:
providing a substrate having a display area and a non-display area;
forming a plurality of scan lines, a plurality of data lines and a plurality of active devices electrically connected to the scan lines and the data lines in the display area;
forming a plurality of first wires and a plurality of first pads electrically connected to the first wires in the non-display area at the same time;
forming a plurality of second wires and a plurality of second pads electrically connected to the second wires in the non-display area at the same time, wherein the first pads and the second pads are disposed in different layers and arranged alternately;
forming an insulating layer on the substrate for covering the data lines, the scan lines, the active devices, the first pads, the second pads, the first wires and the second wires;
forming an organic planarization layer on the insulating layer, wherein the organic planarization layer has a plurality of first openings, a plurality of second openings and a plurality of third openings;
etching the insulating layer by using the organic planarization layer as an etching mask to form a plurality of first contact vias, a plurality of second contact vias and a plurality of third contact vias, wherein each of the first contact vias expose the corresponding first pad, each of the second contact vias expose the corresponding second pad, and each of the third contact vias expose a portion of the corresponding active device; and
forming a plurality of first pad electrodes and a plurality of second pad electrodes on the organic planarization layer in the non-display area, and forming a plurality of pixel electrodes on the organic planarization layer in the display area, wherein the first pad electrodes are electrically connected to the first pads through the first contact vias, the second pad electrodes are electrically connected to the second pads through the second contact vias, and the pixel electrodes are electrically connected to the active devices through the third contact vias.

13. The manufacturing method according to claim 12, wherein a material of the first pads is different from a material of the second pads.

14. The manufacturing method according to claim 12, further comprising reducing a thickness of the organic planarization layer in the non-display area such that the thickness of the organic planarization layer in the non-display area is smaller than that of the organic planarization layer in the display area.

15. The manufacturing method according to claim 12, further comprising forming a plurality of first connecting lines and a plurality of second connecting lines in the non-display area, wherein the first connecting lines are electrically connected to the first pads, and the second connecting lines are electrically connected to the second pads.

16. The manufacturing method according to claim 15, further comprising forming a plurality of fourth contact vias in the organic planarization layer and the insulating layer in the non-display area, wherein the first pad electrode are electrically connected to the first connecting lines through the fourth contact vias.

17. The manufacturing method according to claim 15, wherein the substrate further has a testing area, the manufacturing method further comprising:
forming a plurality of switching devices in the testing areas, the switching devices electrically connected to the first connecting lines and the second connecting lines.

18. The manufacturing method according to claim 17, further comprising forming a plurality of testing devices in the testing area, wherein the testing devices are electrically connected to the switching devices.

19. The manufacturing method according to claim 15, wherein the substrate further has a testing area, the manufacturing method further comprising:
forming a plurality of testing device in the testing area, wherein the testing devices are electrically connected to the first connecting lines and the second connecting lines.
